(19) United States
(12) Patent Application Publication
(10) Pub. No.: US 2005/0224897 A1
(43) Pub. Date: Oct. 13, 2005

(54) High-K gate dielectric stack with buffer layer to improve threshold voltage characteristics

(75) Inventors: Shang-Chih Chen, Jiadong Township (TW); Chih-Hao Wang, Hsin-chu (TW); Yee-Chia Yeo, Singapore (SG); Feng-Der Chin, Hsinchu (TW); Chuan-Yi Lin, Tainan City (TW)

Correspondence Address: TUNG & ASSOCIATES, Suite 120, 838 W. Long Lake Road, Bloomfield Hills, MI, 48302, US

(73) Assignee: Taiwan Semiconductor Manufacturing Co., Ltd.

(21) Appl. No.: 10/809,974

(22) Filed: Mar. 26, 2004

(51) Int. Cl. H01L 39/22

(52) U.S. Cl. 257/410; 257/411; 257/900

(57) ABSTRACT

A high-K gate dielectric stack for a MOSFET gate structure to reduce Voltage threshold (Vₜₕ) shifts and method for forming the same, the method including providing a high-K gate dielectric layer over a semiconductor substrate; forming a buffer dielectric layer on the high-K gate dielectric including a dopant selected from the group consisting of a metal, a semiconductor, and nitrogen; forming a gate electrode layer on the buffer dielectric layer; and, lithographically patterning the gate electrode layer and etching to form a gate structure.

### FIELD OF THE INVENTION

The present invention relates generally to high-K CMOS transistor gate stacks and associated fabrication processes in micro-integrated circuit manufacture and more particularly, to a high-K dielectric gate stack including a buffer layer and method of forming the same to avoid a Fermi-level pinning effect due to interfacial reaction and diffusion of gate electrode materials at a high-K gate dielectric interface.

### BACKGROUND OF THE INVENTION

Fabrication of a metal-oxide-semiconductor (MOS) integrated circuit involves numerous processing steps. A gate oxide is typically formed from silicon dioxide formed over a semiconductor substrate. For each MOS field effect transistor (MOSFET) being formed, a gate electrode is formed over the gate dielectric, and dopant impurities are then introduced into the semiconductor substrate to form source and drain regions. Many modern day semiconductor microelectronic fabrication processes form features having less than 0.25 micron critical dimensions, for example more recent devices include features sizes of less than 0.10 microns. As design rules decrease, the size of a gate structures decrease including the physical thicknesses of gate dielectrics. For example, the required thickness of a silicon dioxide layer decreases to less than about 20 Angstroms with concomitant problem of tunneling current leakage.

In order to overcome this phenomenon, an increasing trend in semiconductor microelectronic device fabrication is to use high-K (high dielectric constant materials) in the gate dielectric stack to achieve an equivalent oxide thickness (EOT) with thicker high-K materials. A high dielectric constant allows a thicker gate dielectric to be formed which dramatically reduces tunneling current and consequently gate leakage current, thereby overcoming a severe limitation in the use of SiO₂ as the gate dielectric at smaller device critical dimensions.

There have been, however, difficulties in forming high-k gate dielectrics to achieve acceptable threshold Voltage behavior in CMOS devices. Frequently, a relatively large shift in flatband Voltage or equivalent threshold Voltage occurs when high-K dielectrics are used in a gate dielectric stack for both NMOS and PMOS devices. For example, hafnium oxide (e.g., HfO₂) when used in the gate dielectric stack exhibits a shift of from about 300 mV in NMOS devices and about 700 mV in PMOS devices compared to conventional SiO₂ gate dielectrics.

The presence of undesirable interfacial states and diffusion of metals into the high-K dielectric is believed to contribute to flatband and threshold Voltage shifts. Several approaches, from treating the base oxide layer, to post deposition annealing of the high-K dielectric prior to methods of polysilicon electrode layer deposition have been proposed. Proposed approaches so far have met with limited success, threshold Voltages still exhibiting larges differences (shifts) compared to expected electrical performance. As a result, the integration of high-K gate dielectric gates in gate structures with acceptable electrical behavior including acceptable threshold Voltage behavior in low power CMOS devices remains a problem to be overcome.

Therefore it would be advantageous to develop an improved gate structure and method for forming the same including high-K gate dielectrics in CMOS devices having improved electrical performance including threshold Voltage performance.

It is therefore an object of the invention to provide an improved gate structure and method for forming the same including high-K gate dielectrics in CMOS devices having improved electrical performance including threshold Voltage performance, while overcoming other shortcomings and deficiencies of the prior art.

### SUMMARY OF THE INVENTION

To achieve the foregoing and other objects, and in accordance with the purposes of the present invention, as embodied and broadly described herein, the present invention provides a high-K gate dielectric stack for a MOSFET gate structure to reduce Voltage threshold (Vₜₕ) shifts.

In a first embodiment, the method includes providing a high-K gate dielectric layer over a semiconductor substrate; forming a doped buffer dielectric layer on the high-K gate dielectric including a dopant selected from the group consisting of a metal, a semiconductor, and nitrogen; forming a gate electrode layer on the doped buffer dielectric layer; and, lithographically patterning the gate electrode layer and etching to form a gate structure.

These and other embodiments, aspects and features of the invention will be better understood from a detailed description of the preferred embodiments of the invention which are further described below in conjunction with the accompanying Figures.

### BRIEF DESCRIPTION OF THE DRAWINGS

FIGS. 1A-1F are cross sectional views of a portion of an exemplary gate structure including a high-K gate dielectric including a gate dielectric buffer layer at stages in manufacture according to an embodiment of the present invention.

FIG. 2 is a process flow diagram including several embodiments of the present invention.

### DETAILED DESCRIPTION OF THE PREFERRED EMBODIMENTS

Embodiments of the present invention will now be described in detail with reference to the Figures where like numbered items refer to like structures wherever possible.

The gate structure and method for forming the same of the present invention is explained with respect to exemplary processing steps for forming deep submicron technology MOSFET devices, preferably having a characteristic (critical) dimension (e.g., gate length) less that about 90 nm. It will be appreciated that the method may be used with larger device characteristic dimensions, but that it is most advantageously used with deep sub-micron design rule technologies (e.g., equal to or less than about 90 nm.

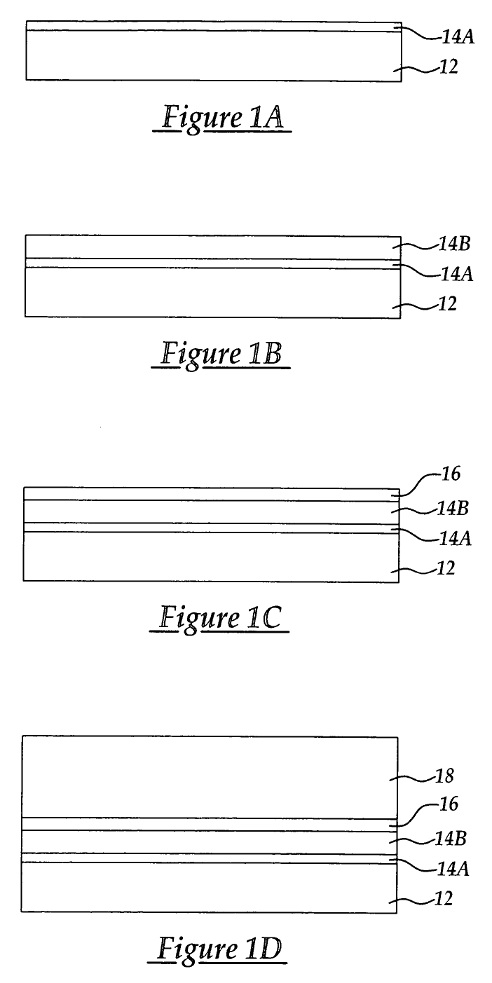

In an exemplary embodiment of the present invention, reference is made to FIGS. 1A-1F where cross sectional schematic views are shown of an exemplary MOSFET device in stages of manufacture according to embodiments of the present invention. For example, referring to FIG. 1A, is shown a semiconductor substrate 12, which may include silicon, strained semiconductor, compound semiconductor, and multi-layered semiconductors, or combinations thereof. For example, the substrate 12 may include, but is not limited to, silicon on insulator (SOI), stacked SOI (SSOI), stacked SiGe on insulator (S—SiGeOI), SiGeOI, and GeOI, or combinations thereof.

Still referring to FIG. 1A, in an exemplary embodiment of the present invention, an optional interfacial layer 14A, also referred to as a base layer, formed of SiO₂, SiON, or SiN, or combinations thereof is formed on the substrate 12. The interfacial layer 14A may be formed by one or more of CVD deposition, wet or dry (plasma) chemical reaction (oxidation), thermal oxidation, and nitridation. The interfacial layer 14A is formed over the semiconductor substrate 12 to a thickness of preferably between about 5 Angstroms to about 30 Angstroms. The interfacial layer 14A may be optionally subjected to surface treatments including chemical, plasma and/or annealing treatments prior to formation of an overlying high-K gate dielectric. It will be appreciated that the high-K dielectric may be formed directly onto the semiconductor substrate 12 without the formation of an interfacial layer 14A. However an interfacial oxide layer e.g., 14A is preferably provided for high-K dielectric stability when using high-K dielectrics such as hafnium oxide (HfO₂). For example, the interfacial layer serves to increase charge carrier mobility, improve a gate dielectric/substrate interface, and prevent reaction between a high-k gate dielectric and the semiconductor substrate 12.

Referring to FIG. 1B, at least one high-K dielectric layer e.g., 14B is then deposited over the interfacial oxide layer 14A by conventional methods. For example the high-K gate dielectric layer 14B is formed by CVD, ALD-CVD, MOCVD, PECVD, PVD, laser ablation, sputter deposition, or combination thereof.

The high-K gate dielectric 14B is preferably formed of metal oxides, metal silicates, metal nitrides, transition metal-oxides, transition metal silicates, metal aluminates, and transition metal nitrides, or combinations thereof. Preferably the dielectric constant of the gate dielectric layer 14B is greater than about 3.9. Exemplary preferred high-K gate dielectric materials include hafnium oxide (HfO₂), aluminum oxide (Al₂O₃), titanium oxide (TiO₂), tantalum oxide (Ta₂O₅)), zirconium oxide (ZrO₂), lanthanum oxide (La₂O₃), cerium oxide (CeO₂), bismuth silicate (Bi₂Si₂O₁₂), tungsten oxide (Wo3), yttrium oxide (Y₂O₃), lanthanum aluminate (LaAlO₃), barium strontium titanate (BaₓSrₓTiO₃), strontium titanate (SrTiO₃), lead zirconate (PbZrO₃), PST, PZN, PZT, PMN, or combinations thereof. The gate dielectric material may be amorphous, polysilicon, crystalline, or combinations thereof.

For example, the gate dielectric layer 14B deposition may take place at a temperature of from about 250° C. to about 1050° C. and may include oxidation or nitridation processes following deposition as well as one or more post deposition annealing process, including furnace or RTA annealing. It will be appreciated that the post deposition annealing processes may be carried out following subsequent buffer layer or gate electrode material deposition and/or gate structure formation as explained below. The post deposition annealing processes may include temperatures from about 300° C. to about 1100° C. The post deposition annealing processes may be carried out in an inert gas, hydrogen, nitrogen, oxygen, or mixtures thereof.

It will be appreciated that the thickness of the high-K gat dielectric layer 14B will vary depending on the equivalent oxide thickness (EOT) desired, for example and EOT of between about 5 Angstroms and 50 Angstroms. For example, the gate dielectric layer may vary between about 40 Angstroms and about 100 Angstroms.

Referring to FIG. 1C, following formation of the high-K gate dielectric layer 14B, an overlying buffer layer 16 is formed over the high-K gate dielectric layer. The buffer layer 16 preferably has a dielectric constant of greater than about 3.9 and preferably has little or not reactivity (bond forming reactions) with the high-K dielectric layer or the subsequently formed overlying gate electrode. Preferably, the equivalent oxide thickness (EOT) for the buffer layer is less than the EOT of the high-K dielectric layer. The buffer layer is preferably doped with nitrogen, a metal or a semiconductor.

In one embodiment, the buffer layer 16 is formed of a non-metal containing dielectric selected from the group consisting of semiconductor-oxide, semiconductor-nitride, oxides, nitrides, silicates and semiconductor-silicates. For example, the buffer layer 16 is doped with nitrogen to form silicon nitrides, silicon oxynitrides, silicate nitrides, and silicate oxynitrides. For example, the buffer layer may be formed of silicon nitride (e.g., SiₓN_{y}) or silicon oxynitride (e.g., SiₓO_{y}N_{z}) or combinations thereof including a dopant gradient having a dopant concentration increasing from a bottom portion of the buffer layer to an upper portion. For example, the buffer layer is gradiently doped to form a higher dielectric constant at a bottom portion and a lower dielectric constant at an upper portion, but preferably having an overall dielectric constant greater than about 3.9.

In another embodiment, the buffer layer 16 is preferably a dielectric layer doped with a metal dopant. For example, the buffer layer is formed of silicates, nitrides (e.g., silicon nitride), or oxynitrides (e.g., silicon oxynitride) including a metal dopant type and level that will avoid a Fermi-level pinning effect, for example the metal dopant having a work function energy level falling about mid-level with respect to a forbidden energy band gap (E_{g}) of a semiconductor gate electrode forming material at the gate electrode/buffer layer interface. For example, to avoid a Fermi-level pinning effect, bonds formed between a metal dopant and a gate electrode semiconductor at an interface preferably have an energy level falling between the Fermi-level for the respective NMOS or PMOS device and E_{g}/2 (mid gap). It will be appreciated that the metal dopant type may be the same or different in an NMOS and PMOS device depending on the Fermi pinning level of bonds formed at the gate electrode/buffer layer interface.

For example, exemplary buffer layer materials include aluminum oxide (e.g., Al₂O₃), aluminum silicate (e.g., AlSi_{X}O_{Y}), or AlSiₓO_{Y}N_{z} for a PMOS gate structure and hafnium oxide (e.g., HfO₂), Hafnium silicate (e.g., HfSi_{X}O_{Y}, or HfSiₓO_{Y}N_{z} for an NMOS device. It will be appreciated that the same buffer layer material may be included for both NMOS and PMOS devices, for example if a Si-metal bond formed at the buffer layer/gate electrode interface falls about midrange within an N or P doped polysilicon forbidden energy bandgap (E_{g}).

Other exemplary materials include metal doped oxides, nitrides, oxynitrides, silicon oxides, silicon nitrides, silicon oxynitrides, silicate nitrides, silicate oxides, and silicate oxynitrides. For example, the same or different metals included in the high-K gate dielectric may be included as a metal dopant in a silicate or oxynitride at a metal doping from about 5 to about 40 atomic percent with respect to the silicon content.

The metal dopant may be uniformly doped throughout the buffer layer or may be gradiently doped. For example, a metal doped silicate nitride such as HfSiₓO_{Y}N_{z} for an NMOS device and AlSiₓO_{Y}N_{z} for a PMOS device is preferably included in the buffer layer having a metal doping at less than about 40 atomic percent with respect to silicon, more preferably less than about 20 atomic percent. Preferably, the same or different metal dopant as is included the high-K gate dielectric layer 14B is included in the buffer layer at a lower concentration. For example one or more of Hf, Al, Ti, Ta, Zr, La, Ce, Bi, W, Y, Ba, Sr, and Pb may be included as a metal dopant in the buffer layer, for example forming a material such as MOₓN_{y}, MSi_{X}O_{y}, MSiₓN_{y}, MₓSiO_{y}N_{z}, where M is a metal dopant. Preferably, the buffer layer has a dielectric constant greater than about 3.9. In forming a gradiently doped buffer layer the direction of metal dopant concentration gradient is preferably from a higher metal dopant concentration at the bottom portion of the buffer layer (high-K dielectric layer/buffer layer interface) to a lower metal dopant concentration in the uppermost portion (buffer layer/gate electrode interface).

Referring to FIG. 1D, following formation of the buffer layer 16, a gate electrode material layer 18 is formed over (on) the buffer layer 16, for example having a thickness less than about 2500 Angstroms. The gate electrode material may include polysilicon, amorphous polysilicon, polysilicon-germanium, metals, metal silicides, metal nitrides, metal oxides, or combinations thereof. Preferably, the gate electrode material at the gate electrode/buffer layer interface is a semiconductor material having a forbidden energy band gap (E_{g}). For example, the portion of the gate electrode at the buffer layer/gate electrode interface is preferably includes a semiconductor material such as polysilicon, amorphous polysilicon, and polysilicon-germanium. The gate electrode layer 18 may be deposited by CVD, LPCVD, ALD-CVD, PECVD, or PVD methods as are known in the art.

Referring to FIG. 1E, a gate structure is then formed to form a gate stack including the various previously formed layers. For example, a patterned gate hardmask is formed on the gate electrode material using conventional photolithographic patterning and plasma assisted etching techniques. The gate stack layers are then etched according to the gate hardmask using a plasma (RIE) etch process to form the gate structure, e.g., 20.

Following the gate etching process, plasma treatment processes plasma source gases such as hydrogen, oxygen, nitrogen, ammonia, and mixtures thereof may be carried out including annealing treatments including one or more of the same preferred gases to form an annealing ambient. Referring to FIG. 1F, conventional processes such as ion implantation to form source/drain doped regions (not shown) and form oxide and/or nitride offset liners e.g., 22A and/or offset spacers e.g., 22B are carried out to complete the formation of the MOSFET device.

Thus, a gate structure and method for forming the same has been presented to improve an electrical performance of a high-K gate dielectric. For example, the buffer layer formed on the top portion of the high-K gate dielectric according to preferred embodiments accomplishes several beneficial functions including avoiding Fermi-level pinning at a high-K gate/gate electrode interface, for example caused by the formation of interface metal-Si bonds. The buffer layer is preferably doped with a dopant type and level to reduce a Voltage threshold (Vₜₕ) shift compared to the absence of the buffer layer. Preferably, the buffer dielectric layer dopant type and dopant level reduces Voltage threshold (Vₜₕ) shift less than about half of the forbidden energy bandgap (E_{g}) at the gate electrode/doped buffer dielectric interface. For example, in an exemplary implementation, silicon (polysilicon) has a forbidden energy bandgap (E_{g}) of about 1.12 eV, where the buffer layer reduces the Voltage threshold shift to less than half that amount (e.g., E_{g}), even more preferably less than about one quarter of that amount.

For example, it has been found that without a buffer layer, according to prior art processes, that ion implants to adjust a Voltage threshold shift (Vₜₕ) are insufficient to recover a desired Voltage threshold (Vₜₕ) following formation of interfacial chemical bonds at a high-K dielectric layer/gate electrode interface. As a result, formation of a buffer layer according to embodiments of the present invention improves device performance by providing more stable Voltage thresholds and avoiding excessive Voltage threshold shifts in MOSFET device operation. In addition, the buffer layer has the added advantage of preventing interdiffusion of metals, e.g., Si and high-K dielectric gate metals across a gate electrode/high-K dielectric gate interface, further improving device performance reliability. In addition, the buffer layer advantageously reduces oxygen diffusion through the high-K dielectric gate to the interfacial oxide to avoid lowering a dielectric constant, thereby avoiding device performance degradation.

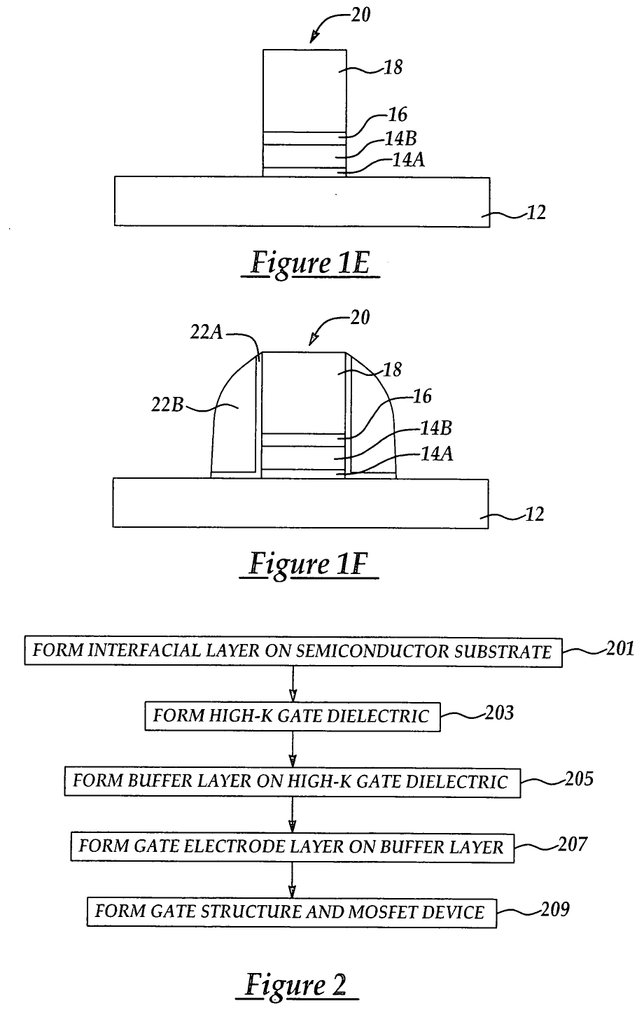

Referring to FIG. 2 is a process flow diagram including several embodiments of the present invention. In process 201, an interfacial oxide layer is optionally formed on a semiconductor substrate. In process 203, at least one high-K gate dielectric layer, is formed on the interfacial oxide. In process 205, a buffer layer according to preferred embodiments is formed on the high-K gate dielectric layer. In process 207, a gate electrode layer is formed over the buffer layer. In process 209, a MOSFET gate structure is formed.

While the embodiments illustrated in the Figures and described above are presently preferred, it should be understood that these embodiments are offered by way of example only. The invention is not limited to a particular embodiment, but extends to various modifications, combinations, and permutations as will occur to the ordinarily skilled artisan that nevertheless fall within the scope of the appended claims.

1. A method for a high-K gate dielectric stack for a MOSFET device gate structure to reduce Voltage threshold (Vₜₕ) shift in a completed MOSFET device comprising the steps of:
providing a high-K gate dielectric layer over a semiconductor substrate substrate;
forming a buffer dielectric layer on the high-K gate dielectric comprising a dopant selected from the group consisting of a metal, a semiconductor, and nitrogen;
forming a gate electrode layer on the buffer dielectric layer; and,
lithographically patterning the gate electrode layer and etching to form a gate structure.

2. The method of claim 1, wherein the wherein the buffer dielectric layer dopant type and dopant level is selected to reduce a Voltage threshold (Vₜₕ) shift.

3. The method of claim 1, wherein buffer dielectric layer dopant type and dopant level is selected to reduce a Voltage threshold (Vₜₕ) shift to less than about half of the forbidden energy bandgap (Eg).

4. The method of claim 1, further comprising forming an interfacial layer on the semiconductor substrate prior to the step of forming a high-K dielectric layer.

5. The method of claim 4, wherein the interfacial layer is selected from the group consisting of silicon dioxide, nitrided silicon dioxide, silicon nitride and silicon oxynitride.

6. The method of claim 1, wherein the buffer dielectric layer has a dielectric constant of greater than about 3.9.

7. The method of claim 1, wherein the buffer dielectric layer comprises a non-metal containing dielectric selected from the group consisting of semiconductor-oxide, semiconductor-nitride, oxides, nitrides, and silicates.

8. The method of claim 1, wherein the buffer dielectric layer comprises a nitrogen doped dielectric selected from the group consisting of silicon nitrides, silicon oxynitrides, silicate nitrides, and silicate oxynitrides.

9. The method of claim 1, wherein the dopant concentration is graded in decreasing concentration from the high-K dielectric layer/buffer layer interface toward the gate electrode layer.

10. The method of claim 1, wherein the buffer dielectric layer comprises a dielectric including metal dopants.

11. The method of claim 10, wherein the dielectric is selected from the group consisting of oxides, nitrides, oxynitrides, silicon oxides, silicon nitrides, silicon oxynitrides, silicate nitrides, silicate oxides, and silicate oxynitrides.

12. The method of claim 10, wherein the metal dopant concentration is from about 5 atomic percent to about 40 atomic percent.

13. The method of claim 10, wherein the metal dopants are selected from the group consisting of Hf, Al, Ti, Ta, Zr, La, Ce, Bi, W, Y, Ba, Sr, and Pb.

14. The method of claim 10, wherein the metal dopants are selected from the group consisting of Hf and Al.

15. The method of claim 10, wherein different metal dopants comprise PMOS and NMOS gate structures.

16. The method of claim 15, wherein Hf comprises the metal dopants in a NMOS gate structure and Al comprises the metal dopants used in a PMOS gate structure.

17. The method of claim 1, wherein the buffer dielectric layer comprises HfO₂ in a NMOS gate structure and Al₂O₃ in a PMOS gate structure.

18. The method of claim 1, wherein the high-k dielectric layer is selected from the group consisting of metal oxides, metal silicates, metal nitrides, transition metal-oxides, transition metal silicates, metal aluminates, transition metal nitrides, and combinations thereof.

19. The method of claim 1, wherein the high-k dielectric layer is selected from the group consisting of hafnium oxide, aluminum oxide, titanium oxide, tantalum oxide, zirconium oxide, lanthanum oxide, cerium oxide, bismuth silicate, tungsten oxide, yttrium oxide, lanthanum aluminate, barium strontium titanate, strontium titanate, lead zirconate, PST, PZN, PZT, PMN, and combinations thereof.

20. The method of claim 1, wherein the gate electrode layer comprises materials selected from the group consisting of polysilicon, polysilicon-germanium, metals, metal silicides, and combinations thereof.

21. The method of claim 1, wherein the semiconductor substrate comprises material selected from the group consisting of silicon on insulator (SOI), SiGe on insulator (SiGeOI), and germanium on insulator (GeOI), and combinations thereof.

22. A gate structure with a reduced Voltage threshold (Vₜₕ) shift comprising:
a high-K gate dielectric layer disposed over a semiconductor substrate; and,
a buffer dielectric layer on the high-K gate dielectric the buffer layer comprising dopants selected from the group consisting of a metal, a semiconductor, and nitrogen; and,
a gate electrode layer on the buffer dielectric layer.

23. The gate structure of claim 21, wherein the wherein the buffer dielectric layer dopant type and dopant level reduces a Voltage threshold (Vₜₕ) shift compared to the absence of the doped dielectric buffer layer.

24. The gate structure of claim 21, wherein buffer dielectric layer dopant type and dopant level reduces Voltage threshold (Vₜₕ) shift less than about half of the forbidden energy bandgap.

25. The gate structure of claim 21, further comprising an interfacial layer on the semiconductor substrate.

26. The gate structure of claim 21, wherein the interfacial layer is selected from the group consisting of silicon dioxide, nitrided silicon dioxide, silicon nitride and silicon oxynitride.

27. The gate structure of claim 21, wherein the buffer dielectric layer has a dielectric constant of greater than about 3.9.

28. The gate structure of claim 21, wherein the buffer dielectric layer comprises a non-metal containing dielectric selected from the group consisting of semiconductor-oxide, semiconductor-nitride, oxides, nitrides, and silicates.

29. The gate structure of claim 21, wherein the buffer dielectric layer comprises a nitrogen doped dielectric selected from the group consisting of silicon nitrides, silicon oxynitrides, silicate nitrides, and silicate oxynitrides.

30. The gate structure of claim 21, wherein the dopant concentration is graded in decreasing concentration from the high-K dielectric layer/buffer layer interface toward the gate electrode layer.

31. The gate structure of claim 21, wherein the buffer dielectric layer comprises a dielectric including metal dopants.

32. The gate structure of claim 31, wherein the dielectric is selected from the group consisting of oxides, nitrides, oxynitrides, silicon oxides, silicon nitrides, silicon oxynitrides, silicate nitrides, silicate oxides, and silicate oxynitrides.

33. The gate structure of claim 31, wherein the metal dopant concentration is from about 5 atomic percent to about 40 atomic percent.

34. The gate structure of claim 31, wherein the metal dopants are selected from the group consisting of Hf, Al, Ti, Ta, Zr, La, Ce, Bi, W, Y, Ba, Sr, and Pb.

35. The gate structure of claim 31, wherein the metal dopants are selected from the group consisting of Hf and Al.

36. The gate structure of claim 21, wherein different metal dopants comprise PMOS and NMOS gate structures.

37. The gate structure of claim 36, wherein Hf comprises the metal dopants in a NMOS gate structure and Al comprises the metal dopants in a PMOS gate structure.

38. The gate structure of claim 21, wherein the buffer dielectric layer comprises HfO₂ in a NMOS gate structure and Al₂O₃ in a PMOS gate structure.

39. The gate structure of claim 21, wherein the high-k dielectric layer is selected from the group consisting of metal oxides, metal silicates, metal nitrides, transition metal-oxides, transition metal silicates, metal aluminates, transition metal nitrides, and combinations thereof.

40. The gate structure of claim 21, wherein the high-k dielectric layer is selected from the group consisting of hafnium oxide, aluminum oxide, titanium oxide, tantalum oxide, zirconium oxide, lanthanum oxide, cerium oxide, bismuth silicate, tungsten oxide, yttrium oxide, lanthanum aluminate, barium strontium titanate, strontium titanate, lead zirconate, PST, PZN, PZT, PMN, and combinations thereof.
